(19) United States
(12) Patent Application Publication
(10) Pub. No.: US 2026/0271451 A1
(43) Pub. Date: Sep. 10, 2026

(54) DISPLAY DEVICE, METHOD FOR MANUFACTURING THE SAME AND ELECTRONIC DEVICE

(71) Applicant: Samsung Display Co., Ltd., Yongin-si (KR)

(72) Inventors: Moon Won CHANG, Yongin-si (KR); Jae Gwang UM, Yongin-si (KR); Tae Hee LEE, Yongin-si (KR)

(21) Appl. No.: 19/429,945

(22) Filed: Dec. 22, 2025

(30) Foreign Application Priority Data
Mar. 6, 2025 (KR) 10-2025-0028991
Apr. 8, 2025 (KR) 10-2025-0045330

(51) Int. Cl. H10H 29/41; H10H 20/01; H10H 20/831; H10H 20/84; H10H 29/01; H10H 29/49

(52) U.S. Cl. CPC H10H 29/41; H10H 20/017; H10H 20/032; H10H 20/034; H10H 20/8312; H10H 20/8314; H10H 20/84; H10H 29/0364; H10H 29/49

(57) ABSTRACT

A display device, a method of manufacturing the same, and an electronic device are provided. The display device includes: a substrate; a pixel electrode and a common electrode on the substrate; a first organic adhesive layer on the pixel electrode and the common electrode; a second organic adhesive layer on the first organic adhesive layer; and a light emitting element on the second organic adhesive layer, the light emitting element comprising a semiconductor stack, a first contact electrode, and a second contact electrode.

### CROSS-REFERENCE TO RELATED APPLICATION

This application claims priority to, and the benefit of, Korean Patent Application No. 10-2025-0028991, filed on Mar. 6, 2025, and Korean Patent Application No. 10-2025-0045330, filed on Apr. 8, 2025 in the Korean Intellectual Property Office, the entire disclosure of which is incorporated by reference herein.

### BACKGROUND

### 1. Field

The present disclosure relates to a display device, a method for manufacturing the same, and an electronic device.

### 2. Description of the Related Art

With the development of the information society, the demand for display devices for displaying images is increasing in various forms. The display device may be a flat panel display such as a liquid crystal display, a field emission display, a light emitting display, and/or the like.

The light emitting display device may be implemented as an organic light emitting display device including an organic light emitting diode (OLED) element as the light emitting element, an inorganic light emitting display device including an inorganic semiconductor element as the light emitting element, or a ultra-small light emitting diode display device including a ultra-small light emitting diode element (or micro light emitting diode element) as the light emitting element.

### SUMMARY

Aspects and features of embodiments of the present disclosure are to provide a display device and a manufacturing method thereof that may lower the contact resistance caused by contaminant particles that may occur during the transfer of a light emitting element and lower the possibility of causing dark spots when the display panel is illuminated.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes: a substrate; a pixel electrode and a common electrode on the substrate; a first organic adhesive layer on the pixel electrode and the common electrode; a second organic adhesive layer on the first organic adhesive layer; and a light emitting element on the second organic adhesive layer, the light emitting element comprising a semiconductor stack, a first contact electrode, and a second contact electrode.

According to one or more embodiments, a width of the first organic adhesive layer is greater than a width of the second organic adhesive layer.

According to one or more embodiments, the width of the second organic adhesive layer is equal to or smaller than a width of the light emitting element.

According to one or more embodiments, the first organic adhesive layer and the second organic adhesive layer comprise different materials.

According to one or more embodiments, the first organic adhesive layer and the second organic adhesive layer comprise a same material.

According to one or more embodiments, the first contact electrode extends laterally from a top surface of the light emitting element, and the second contact electrode extends laterally from the top surface of the light emitting element and is spaced from the first contact electrode.

According to one or more embodiments, the display device further includes a first connection electrode connecting the pixel electrode and the first contact electrode, and a second connection electrode connecting the common electrode and the second contact electrode.

According to one or more embodiments, the light emitting element further includes: a conductive layer on the semiconductor stack; and a protective film on side surfaces of the conductive layer and side surfaces of the semiconductor stack, wherein the first contact electrode is on the protective film and is connected to the conductive layer that is exposed and not covered by the protective film, wherein the second contact electrode is on the protective film and is in a hole penetrating the conductive layer and a portion of the semiconductor stack.

According to one or more embodiments, the semiconductor stack further includes: a first semiconductor layer on the second organic adhesive layer, the first semiconductor layer comprising a semiconductor material layer doped with a first conductive dopant; an active layer on the first semiconductor layer; and a second semiconductor layer on the active layer, the second semiconductor layer comprising a semiconductor material layer doped with a second conductive dopant, wherein the first contact electrode is on a first side of the first semiconductor layer, a first side of the active layer, and a portion of a first side of the second semiconductor layer, wherein the second contact electrode is on a second side of the first semiconductor layer, a second side of the active layer, and a portion of a second side of the second semiconductor layer.

According to one or more embodiments, a method for manufacturing a display device includes: forming a second organic adhesive layer on one surface of a light emitting element on a first substrate; forming a first organic adhesive layer on a pixel electrode and a common electrode on a second substrate; adhering the first organic adhesive layer and the second organic adhesive layer to transfer the light emitting element onto the second substrate; and forming a first connection electrode connecting the pixel electrode and a first contact electrode of the light emitting element and a second connection electrode connecting the common electrode and a second contact electrode of the light emitting element.

According to one or more embodiments, the first substrate comprises a light transmitting support layer and an adhesive layer on the light transmitting support layer and having adhesive strength, wherein the light emitting element is adhered to the adhesive layer, wherein the adhesive strength between the first organic adhesive layer and the second organic adhesive layer is stronger than the adhesive strength between the adhesive layer of the first substrate and the light emitting element.

According to one or more embodiments, the adhesive layer of the first substrate and the second organic adhesive layer comprise a same material.

According to one or more embodiments, the first organic adhesive layer and the second organic adhesive layer comprise different materials.

According to one or more embodiments, the first organic adhesive layer and the second organic adhesive layer comprise a same material.

According to one or more embodiments, in the transferring the light emitting element onto the second substrate by bonding the first organic adhesive layer and the second organic adhesive layer, the first substrate is located on the second substrate so that the first organic adhesive layer and the second organic adhesive layer face each other and are brought into contact, and heat and pressure are applied between the first organic adhesive layer and the second organic adhesive layer to physically and chemically bond the first organic adhesive layer and the second organic adhesive layer, and the first substrate is separated and removed from the light emitting element.

According to one or more embodiments, a width of the first organic adhesive layer is greater than a width of the second organic adhesive layer.

According to one or more embodiments, the width of the second organic adhesive layer is equal to or smaller than a width of the light emitting element.

According to one or more embodiments, the forming the second organic adhesive layer on the one surface of the light emitting element on the first substrate includes: forming a second semiconductor material layer, an active material layer, a first semiconductor material layer, and a conductive material layer on a semiconductor substrate; etching the second semiconductor material layer, the active material layer, the first semiconductor material layer, and the conductive material layer to form light emitting elements, each of the light emitting elements comprising a second semiconductor layer, an active layer, a first semiconductor layer, and a conductive layer; forming a protective material layer around each of the light emitting elements, and patterning the protective material layer to form a protective film; forming the first contact electrode and the second contact electrode on the protective film using a mask pattern; transferring the light emitting elements to the first substrate so that the conductive layer of each of the light emitting elements faces the first substrate; and forming the second organic adhesive layer on the second semiconductor material layer.

According to one or more embodiments, the method further includes sequentially forming an organic layer for planarizing the light emitting element and a color filter overlapping the light emitting element.

According to one or more embodiments, an electronic device includes: a display panel; a window on the display panel; and a bottom cover located below the display panel, wherein the display panel includes: a substrate; a pixel electrode and a common electrode on the substrate; a first organic adhesive layer on the pixel electrode and the common electrode; a second organic adhesive layer on the first organic adhesive layer; and a light emitting element on the second organic adhesive layer, the light emitting element comprising a semiconductor stack, a first contact electrode, and a second contact electrode.

In a display device and a manufacturing method thereof according to one or more embodiments of the present disclosure, the possibility of causing dark spots when the display panel is turned on due to contaminant particles that may occur during the thermal compression process of the light emitting element may be lowered and the reliability of the panel may be improved.

However, the present disclosure is not limited to the aforementioned effects, aspects, and features, and various other aspects and features are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating an example of cross-section of a display panel corresponding to the lines I1-I1′, I2-I2′, and I3-I3′ of FIG. 5.

FIG. 7 is a cross-sectional view illustrating an example of an area A in FIG. 6 in detail.

FIG. 8 is a cross-sectional view illustrating another example of the area A of FIG. 6 in detail.

FIG. 9 is a cross-sectional view illustrating another example of the area A of FIG. 6 in detail.

FIG. 10 is a cross-sectional view illustrating another example of the area A of FIG. 6 in detail.

FIG. 11 is a cross-sectional view illustrating another example of the area A of FIG. 6 in detail.

FIG. 12 is a layout diagram illustrating pixels of a display area according to one or more embodiments.

FIG. 13 is a cross-sectional view illustrating an example of a cross-section of a display panel corresponding to the II-II′ line of FIG. 12.

FIG. 14 is a cross-sectional view illustrating an example of an area B of FIG. 13 in detail.

FIG. 15 is a cross-sectional view illustrating another example of an area B of FIG. 13 in detail.

FIG. 16 is a flowchart illustrating a method of manufacturing a display device according to one or more embodiments.

FIG. 17-25 are example drawings to illustrate a method of manufacturing a display device according to one or more embodiments.

FIGS. 26 and 27 are example drawings illustrating a smart watch including a display device according to one or more embodiments.

FIG. 28 is an exploded perspective view of a smart watch including a display device according to one or more embodiments.

FIG. 29 is an example views of a virtual reality (VR) device including a display device according to one or more embodiments.

FIG. 30 is an example view of a VR device including a display device according to one or more embodiments.

FIG. 31 is an example view illustrating a vehicle instrument cluster and center fascia including display devices according to one or more embodiments.

FIG. 32 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and/or hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

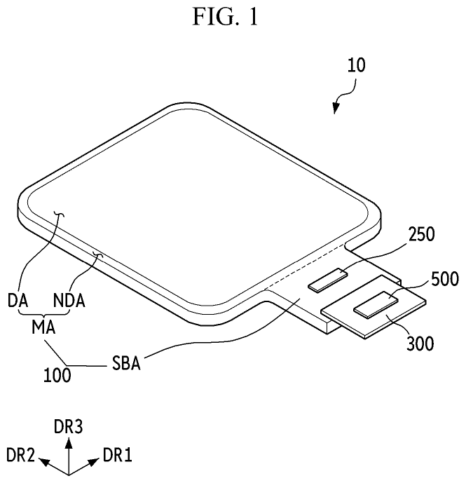

FIG. 1 is a schematic perspective view illustrating a display device according to one or more embodiments.

Referring to FIG. 1, a display device 10 may be for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the disclosure is not limited thereto. On the other hand, hereinafter, an ultra-small light emitting diode is described as a light emitting element for convenience of explanation.

The display device 10 may include a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a selected or predetermined curvature) or may be formed at a right angle. The planar shape of the display panel 100 is not limited to a rectangle, but may be formed in other polygonal, circular, or oval shapes. The display panel 100 may be formed flat but is not limited thereto. For example, the display panel 100 may be formed at the left and right ends and may include curved portions with a constant curvature or a changing curvature. The display panel 100 may be flexibly formed to be bent, curved, bent, folded, and/or rolled.

The substrate SUB of the display panel 100 may include a main area MA and a sub-area SBA.

The main area MA may include a display area DA that displays an image and a non-display area NDA that is a surrounding area of the display area DA. The display area DA may include multiple pixels that display an image. Each pixel may include multiple sub-pixels. For example, each of the pixels may include a first sub-pixel that emits light of a first color, a second sub-pixel that emits light of a second color, and a third sub-pixel that emits light of a third color. However, the present disclosure is not limited thereto.

The sub-area SBA may protrude from a side of the main area MA in the second direction DR2. Although FIG. 1 illustrates the sub-area SBA being unfolded, the sub-area SBA may be bent, and for example, may be disposed on the lower surface of the display panel 100. In case that the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. The display driving circuit 250 may be attached to the circuit substrate 300 using a chip on film (COF) method.

The circuit substrate 300 may be attached to an end of the sub-area SBA of the display panel 100. For example, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate multiple panel driving voltages according to an external power supply voltage. The power supply circuit 500 may be formed as an integrated circuit (IC) and attached to the circuit substrate 300 using a COF method.

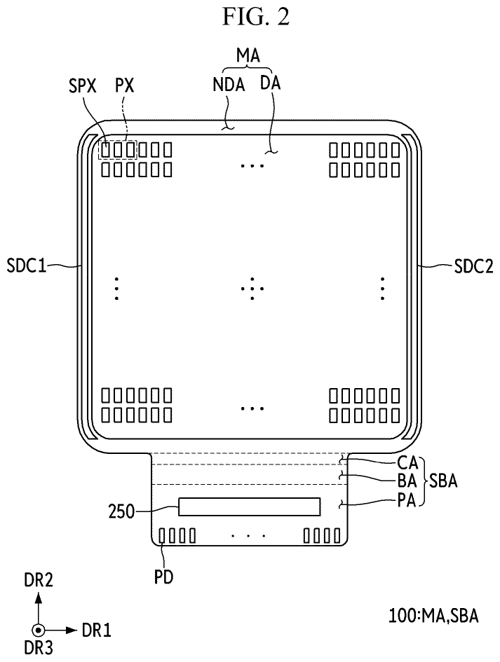

FIG. 2 is a schematic layout illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be disposed in the center of the main area MA.

The display area DA may include multiple pixels PX for displaying an image, and each of multiple pixels PX may include multiple sub-pixels SPX. A pixel PX may be defined as a sub-pixel group of the smallest unit capable of expressing a white gray level (e.g., white grayscale value).

The non-display area NDA may be disposed adjacent to the display area DA. The non-display area NDA may be an area disposed outside the display area DA. The non-display area NDA may be around (e.g., may surround) the display area DA. The non-display area NDA may be an edge area of the display panel 100.

A first scan driving portion SDC1 and a second scan driving portion SDC2 may be disposed in the non-display area NDA. The first scan driving portion SDC1 may be disposed on a side (e.g., the left side) of the display panel 100, and the second scan driving portion SDC2 may be disposed on another side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from a side of the main area MA in the second direction DR2. The length of the sub-area SBA in the second direction DR2 may be smaller than the length of the main area MA in the second direction DR2. The length in the first direction DR1 of the sub-area SBA may be less than the length in the first direction DR1 of the main area MA or may be substantially equal to the length in the first direction DR1 of the main area MA. The sub-area SBA may be curved and may be disposed at a lower portion of the display panel 100. For example, the sub-area SBA may overlap the main area MA in the third direction DR3.

The sub-area SBA may include a connection area CA, a pad area PA, and a bending area BA.

The connection area CA may be an area protruding from a side of the main area MA in the second direction DR2. A side of the connection area CA may be in contact with the non-display area NDA of the main area MA, and another side of the connection area CA may be in contact with the bending area BA.

The pad area PA may be an area where the pads PD and the display driving circuit 250 may be disposed. The display driving circuit 250 may be attached to the driving pads of the pad area PA using a conductive adhesive member such as an anisotropic conductive film. The circuit substrate 300 may be attached to the pads PD of the pad area PA using a conductive adhesive member such as an anisotropic conductive film. A side of the pad area PA may be in contact with the bending area BA.

The bending area BA may be a bent area. In case that the bending area BA is bent, the pad area PA may be disposed below the connection area CA and below the main area MA. The bending area BA may be disposed between the connection area CA and the pad area PA. A side of the bending area BA may be in contact with the connection area CA, and another side of the bending area BA may be in contact with the pad area PA.

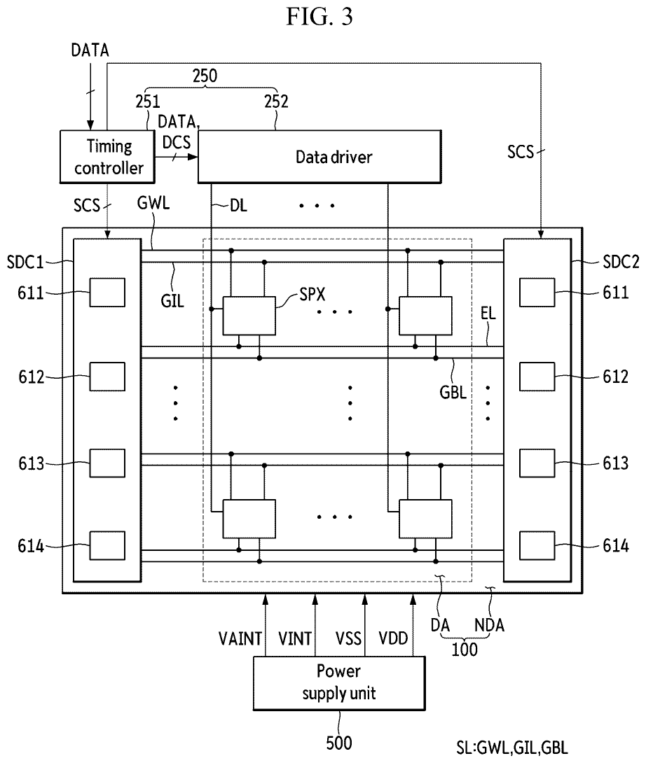

FIG. 3 is a schematic block diagram illustrating a display device according to one or more embodiments.

Referring to FIG. 3, the display area DA may include multiple pixels PX (each of the pixels PX including a plurality of sub-pixel SPX), multiple scan lines SL, multiple emission control lines EL, and multiple data lines DL.

Multiple pixels PX may be arranged in a matrix form along the first direction DR1 and the second direction DR2. For example, the plurality of pixels PX may be arranged along rows and columns of a matrix form along the first direction DR1 and the second direction DR2. Multiple scan lines SL and multiple emission control lines EL may extend in the first direction DR1 and be disposed along the second direction DR2. Multiple data lines DL may extend in the second direction DR2 and may be disposed along the first direction DR1. Multiple scan lines SL may include a multiple write scan lines GWL, multiple initialization scan lines GIL, and multiple bias scan lines GBL.

Each of multiple sub-pixels SPX may be electrically connected to a write scan line GWL from among multiple write scan lines GWL, an initialization scan line GIL from among multiple initialization scan lines GIL, a bias scan line GBL from among multiple bias scan lines GBL, an emission control line EL from among multiple emission control lines EL, and a data line DL from among multiple data lines DL. Each of multiple sub-pixels SPX may be supplied with a data voltage of the data line DL according to the write scan signal of the write scan line GWL and may emit light emitting elements according to the data voltage.

The non-display area NDA may include a first scan driving portion SDC1, a second scan driving portion SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit (e.g., a timing controller) 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 may include a timing control circuit (e.g., a timing controller) 251 and a data driving circuit (e.g., a data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. For example, the sub-pixels SPX may be selected by the write scan signals of the first scan driving portion SDC1 and the second scan driving portion SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit (e.g., a power supply unit) 500 may generate multiple panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

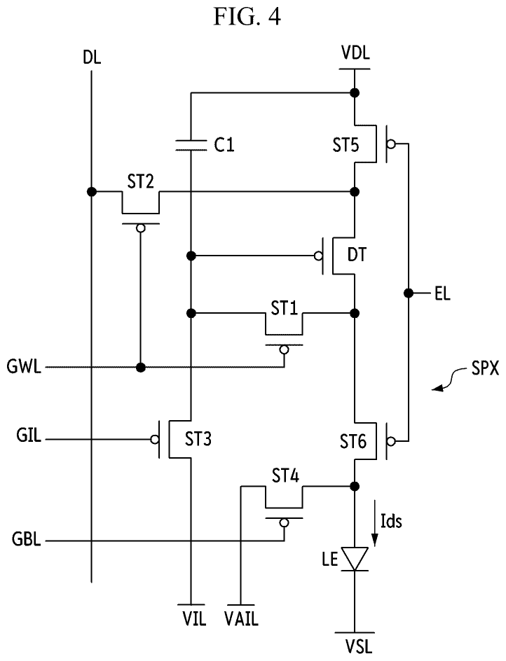

FIG. 4 is a schematic diagram of an equivalent circuit of a sub-pixel according to one or more embodiments.

Referring to FIG. 4, a sub-pixel SPX according to one or more embodiments may be electrically connected to scan lines GWL, GIL, and GBL, an emission control line EL, and a data line DL. For example, the sub-pixel SPX may be electrically connected to a write scan line GWL, an initialization scan line GIL, a bias scan line GBL, an emission control line EL, and a data line DL.

The sub-pixel SPX according to one or more embodiments may include a driving transistor DT, switching elements, a capacitor, and a light emitting element LE. The switching elements include first to sixth transistors ST1, ST2, ST3, ST4, ST5, and ST6.

The driving transistor DT may include a gate electrode, a first electrode, and a second electrode. The driving transistor DT controls a drain-source current (Ids, hereinafter referred to as “driving current”) flowing between the first electrode and the second electrode according to a data voltage applied to the gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE may be electrically connected to the first electrode of the fourth transistor ST4 and the second electrode of the sixth transistor ST6, and the cathode electrode may be electrically connected to a second power supply line VSL to which a second power supply voltage is applied.

A capacitor C1 may be formed between the gate electrode of a driving transistor DT and a first power supply line VDL to which a first power supply voltage is applied. The first power supply voltage may be a voltage of a higher level than the second power supply voltage. An electrode of the capacitor C1 may be electrically connected to the gate electrode of the driving transistor DT, and another electrode may be electrically connected to the first power supply line VDL.

As shown in FIG. 4, the first to sixth transistors ST1, ST2, ST3, ST4, ST5, and ST6 and the driving transistor DT may all be formed as p-type MOSFET. For example, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 may be formed as p-type MOSFET and they may be turned on in case that a scan signal of a gate low voltage and an emission control signal are applied to the initialization scan line GIL, the write scan line GWL, the bias scan line GBL, and the emission control line EL, respectively. An electrode of the third transistor ST3 may be connected to a first initialization voltage line VIL to which the third power supply voltage (VINT of FIG. 3) is applied, and an electrode of the fourth transistor ST4 may be connected to a second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

In one or more embodiments, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. For example, the active layers of each of the driving transistor DT, the second transistor ST2, the fourth transistor ST4, the fifth transistor ST5, and the sixth transistor ST6 formed of p-type MOSFETs may be formed of polysilicon, the active layers of each of the first transistor ST1 and the third transistor ST3 formed of an n-type MOSFET may be formed of an oxide semiconductor. Furthermore, because the first transistor ST1 and the third transistor ST3 may be formed as n-type MOSFET, the first transistor ST1 may be turned on in case that a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 may be formed as p-type MOSFET so that they may be turned on in case that a scan signal of the gate low voltage and a light emission control signal of a gate low voltage are applied.

In one or more embodiments, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on in case that a scan signal of a gate high voltage is applied, whereas the remaining transistors DT, ST1, ST2, ST3, ST5, and ST6 may be turned on in case that a scan signal of a gate low voltage and a light emission control signal are applied.

In one or more embodiments, the first to sixth transistors ST1, ST2, ST3, ST4, ST5, and ST6 and the driving transistor DT may all be formed as n-type MOSFET. For example, the active layer of each of the first to sixth transistors ST1, ST2, ST3, ST4, ST5, and ST6 and the driving transistor DT may be formed of an oxide semiconductor and may be turned on in case that a scan signal of a gate high voltage and a light emission control signal are applied.

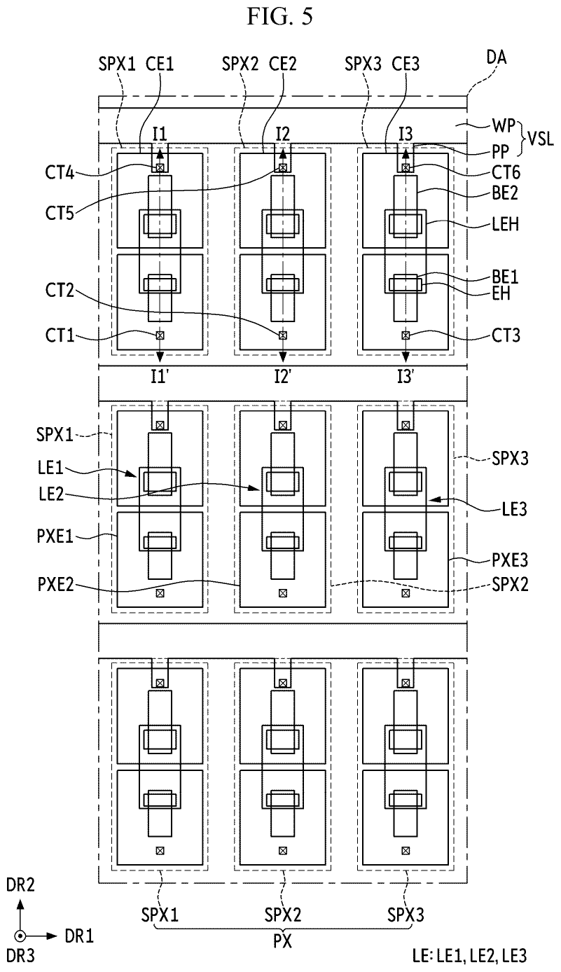

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the three sub-pixels may be the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. To this end, the first light emitting element LE1 may emit light of a first color, the second light emitting element LE2 may emit light of a second color, and the third light emitting element LE3 may emit light of a third color. Here, the light of the first color may be light in a red wavelength band, the light of the second color may be light in a green wavelength band, and the light of the third color may be light in a blue wavelength band. For example, the blue wavelength band may refer to the light having a main peak wavelength in a wavelength band from approximately 370 μm to 460 μm, the green wavelength band may refer to the light having a main peak wavelength in a wavelength band from approximately 480 μm to 560 μm, and the red wavelength band may refer to the light having a main peak wavelength in a wavelength band from approximately 600 μm to 750 μm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a first light emitting element LE1, and a first common electrode CE1. The second sub-pixel SPX2 includes a second pixel electrode PXE2, second light emitting elements LE2, and a second common electrode CE2. The third sub-pixel SPX3 includes a third pixel electrode PXE3, a third light emitting element LE3, and a third common electrode CE3.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged along the second direction DR2. The first pixel electrode PXE1 and the first common electrode CE1 may be spaced (e.g., spaced apart) from each other. The second pixel electrode PXE2 and the second common electrode CE2 may be spaced (e.g., spaced apart) from each other. The third pixel electrode PXE3 and the third common electrode CE3 may be spaced (e.g., spaced apart) from each other.

Each of the first pixel electrode PXE1, the second pixel electrode PXE2, the third pixel electrode PXE3, the first common electrode CE1, the second common electrode CE2, and the third common electrode CE3 may have a rectangular planar shape, but the present disclosure is not limited thereto. Further, the area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

The first common electrode CE1 may be connected to a second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3.

The first connection electrode BE1 is connected to the conductive layer E1 of the light emitting element LE and the pixel electrode PXE1, PXE2, and PXE3. The first connection electrode BE1 may overlap with the hole EH exposing the conductive layer E1. The first connection electrode BE1 may overlap with at least a portion of the pixel electrode PXE1, PXE2, and PXE3.

The second connection electrode BE2 may be connected to the second semiconductor layer SEM2 of the light emitting element LE and the common electrode CE1, CE2, and CE3. The second connection electrode BE2 may overlap with the hole LEH exposing the second semiconductor layer SEM2. The second connection electrode BE2 may overlap with at least a portion of the common electrode CE1, CE2, and CE3.

Each of the second power supply lines VSL may include a line portion WP extending in the first direction DR1 and a protrusion portion PP protruding from the line portion WP in the second direction DR2 and overlapping the common connection holes CT4, CT5, CT6.

The pixel electrodes PXE1, PXE2, and PXE3 may be referred to as anode electrodes or first electrodes, and the common electrodes CE1, CE2, and CE3 may be referred to as cathode electrodes or second electrodes. Each of the pixel electrodes PXE1, PXE2, and PXE3 may be electrically connected to at least one transistor through pixel connection holes CT1, CT2, and CT3.

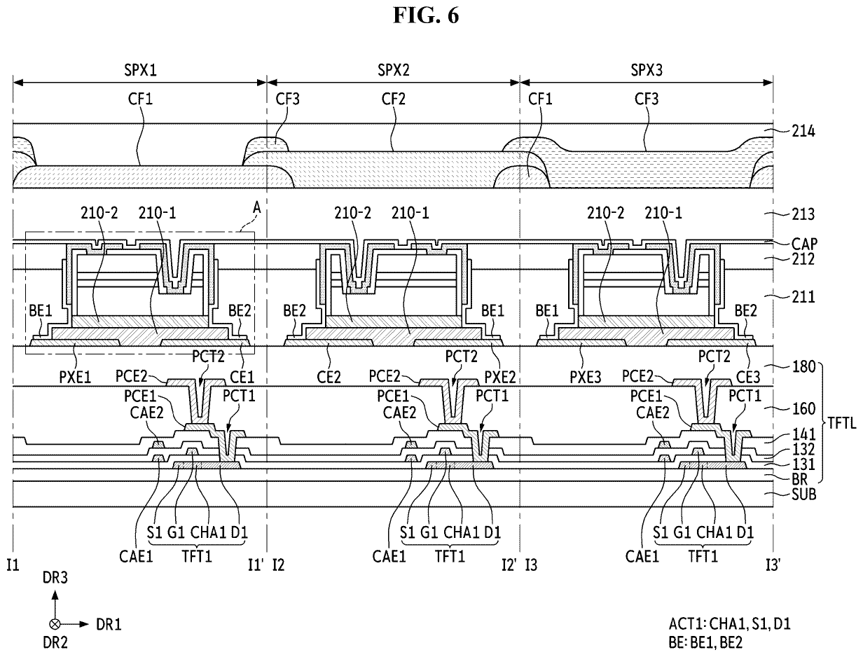

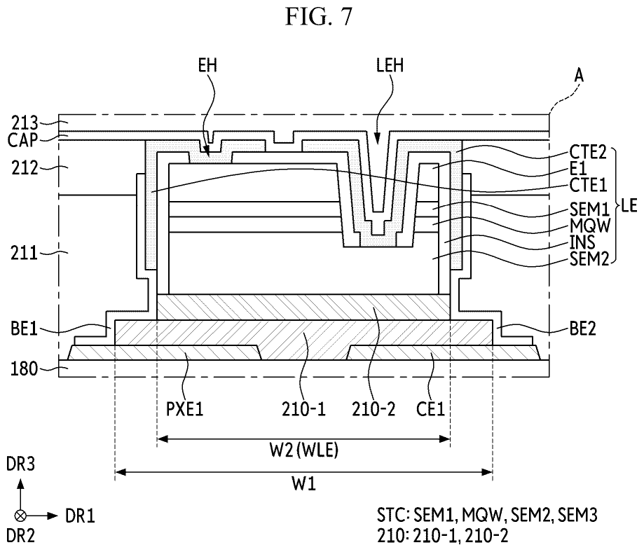

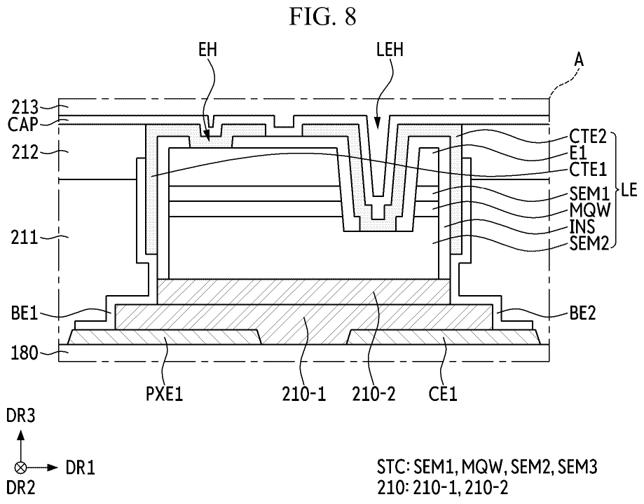

FIG. 6 is a cross-sectional view illustrating an example of cross-section of a display panel corresponding to the lines I1-I1′, I2-I2′, and I3-I3′ of FIG. 5. FIG. 7 is a cross-sectional view illustrating an example of an area A in FIG. 6 in detail. FIG. 8 is a cross-sectional view illustrating another example of the area A of FIG. 6 in detail.

Referring to FIG. 6-7, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film for protecting the transistors of the thin film transistor layer TFTL and the light emitting layer 172 of the light emitting element layer EML from moisture penetrating through the substrate SUB which is vulnerable to moisture permeation. The barrier film BR may be formed of a plurality of inorganic films that are alternately laminated.

A thin-film transistor TFT1 may be arranged on the barrier film BR. The thin-film transistor TFT1 may be either the fourth transistor ST4 or the sixth transistor ST6 shown in FIG. 4. The thin-film transistor TFT1 may include a first active layer ACT1 and a first gate electrode G1.

The first active layer ACT1 of the thin-film transistor TFT1 may be arranged on the barrier film BR. The first active layer ACT1 of the thin-film transistor TFT1 may include polycrystalline silicon, monocrystalline silicon, low-temperature polycrystalline silicon, and/or amorphous silicon. Alternatively, the first active layer ACT1 of the thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin-film transistor TFT1 and on the barrier film BR.

A first gate metal layer may be arranged on the first gate insulating film 131. The first gate metal layer may include a first gate electrode G1 of a thin-film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart (e.g., spaced apart) from each other in FIG. 6, the first gate electrode G1 and the first capacitor electrode CAE1 may be connected to each other.

A second gate insulating film 132 may be arranged on the first gate electrode G1 and the first capacitor electrode CAE1 of the thin-film transistor TFT1 and on the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the thin-film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be arranged on the first source connection electrode PCE1 to planarize a step caused by the thin-film transistor TFT1 and on the first interlayer insulating film 141.

A second data metal layer may be arranged on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization organic film 180 may be arranged on the second source connection electrode PCE2 and on the first planarization organic film 160.

The barrier film BR, the first gate insulating film 131, the second gate insulating film 132, and the interlayer insulating film 141 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include a pixel electrode layer, light emitting elements LE, and an organic adhesive layer 210.

A pixel electrode layer including pixel electrodes PXE1, PXE2, and PXE3 and common electrodes CE1, CE2, and CE3 may be arranged on a second planarization organic film 180. The pixel electrodes PXE1, PXE2, and PXE3 and common electrodes CE1, CE2, and CE3 may be arranged apart (e.g., spaced apart) from each other.

Each of the first pixel electrode PXE1, the second pixel electrode PXE2, and the third pixel electrode PXE3 may be connected to the second source connection electrode PCE2 through connection holes (CT1/CT2/CT3 in FIG. 5) penetrating the second planarization organic film 180. Each of the pixel electrodes PXE1, PXE2, and PXE3 may be connected to the first source region S1 or the first drain region D1 of the thin-film transistor TFT1 through the first source connection electrode PCE1 and the second source connection electrode PCE2. Therefore, a voltage controlled by the thin-film transistor TFT1 may be applied to each of the pixel electrodes PXE1, PXE2, and PXE3.

The common electrode CE1, CE2, and CE3 may be connected to the second power supply VSL through the common connection holes CT4, CT5, and CT6 penetrating the second planarization organic film 180. Therefore, the second driving voltage (VSS in FIG. 3) may be applied to the common electrode CE1, CE2, and CE3.

When the pixel electrode layer is made of a highly reflective metallic material, light emitted from the active layer MQW of the light emitting element LE may be reflected from the pixel electrodes PXE1, PXE2, and PXE3 and the common electrodes CE1, CE2, and CE3 in the downward direction of the light emitting element LE and may be directed to the upward direction of the light emitting element LE. Therefore, because the light loss of the light emitting element LE may be reduced, the light efficiency of the light emitting element LE may be increased.

An organic adhesive layer 210 may be arranged on the pixel electrodes PXE1, PXE2, and PXE3 and the common electrodes CE1, CE2, and CE3 of each of the sub-pixels PXE1, PXE2, and PXE3. The organic adhesive layer 210 temporarily fixes or adheres the light emitting element LE in a process of transferring the light emitting element LE to the display panel 100. For example, the organic adhesive layer 210 may be a film for temporarily adhering an upper member (e.g., the light emitting element LE) on each of the pixel electrodes PXE1, PXE2, and PXE3 and the common electrode CE. To facilitate the temporary adhesion, the thickness of the organic adhesive layer 210 may be greater than the thickness of each of the pixel electrodes PXE1, PXE2, and PXE3 and the common electrode CE and may be greater than the thickness of the contact electrode CTE. The thickness of the organic adhesive layer 210 may be about 2 μm but is not limited thereto.

The organic adhesive layer 210 may include a first organic adhesive layer 210-1 and a second organic adhesive layer 210-2. A second organic adhesive layer 210-2 may be arranged on the first organic adhesive layer 210-1. The first organic adhesive layer 210-1 has a first width W1, and the second organic adhesive layer 210-2 has a second width W2. The first width W1 may be wider than the second width W2.

The second width W2 of the second organic adhesive layer 210-2 may be the same as the width WLE of the light emitting element.

The first organic adhesive layer 210-1 may be a photosensitive organic film such as a photoresist. Alternatively, the first organic adhesive layer 210-1 may be formed from an acrylic resin, an epoxy resin, a phenolic resin, a polyamide resin, a polyimide resin, and/or the like.

The second organic adhesive layer 210-2 may be formed of a PSA type adhesive, such as a polydimethyl siloxane adhesive, a polymethylvinyl siloxane adhesive, and/or the like.

In another modified example, as shown in FIG. 8, the first organic adhesive layer 210-1 and the second organic adhesive layer 210-2 may be formed of the same material. For example, the first organic adhesive layer 210-1 and the second organic adhesive layer 210-2 may be formed of a PSA type adhesive such as a polydimethyl siloxane adhesive and/or a polymethylvinyl siloxane adhesive, but are not limited thereto, and may be formed from an acrylic resin, an epoxy resin, a phenolic resin, a polyamide resin, a polyimide resin, and/or the like.

When the light emitting element LE is bonded to the substrate using a metal, high temperature and pressure may be required to melt the metal. Therefore, the transistors and light emitting elements LE arranged on the substrate may also adopt materials that are robust to temperature. Further, when a high temperature is applied to the light emitting element LE and the substrate, some of the organic film may expand, which may cause the light emitting element LE to be misaligned or may cause damage to the transistor element.

Therefore, when bonding the light emitting element LE to a substrate using an organic adhesive (e.g., an organic adhesive layer), a lower temperature and lower pressure are required compared to when using metal, so damage to the substrate, light emitting element LE, and transistor may be relatively reduced or minimized.

In addition, the first organic adhesive layer 210-1 and the second organic adhesive layer 210-2 may provide greater bonding strength than when only a single organic adhesive layer is present through physical bonding and chemical bonding.

In each of the sub-pixels SPX1, SPX2, and SPX3, the light emitting element LE may be arranged on an organic adhesive layer 210 (e.g., the second organic adhesive layer 210-2. In FIGS. 6 and 7, the light emitting element LE is illustrated as a lateral type micro LED. The lateral type micro LED refers to an LED in which contact electrodes CTE1 and CTE2 are formed on one surface (e.g., a top surface) of the light emitting element LE. The first contact electrode CTE1 and the second contact electrode CTE2 both protrude from the top surface of the light-emitting element LE and are illustrated as lateral type micro-LEDs in which current flows in the lateral direction.

The light emitting element LE may include a substantially vertical side surface as shown in FIG. 7. For example, the light emitting element LE may be patterned through vertical etching and may have a rectangular or square cross-sectional shape in which the width of the top surface and the width of the bottom surface are substantially the same. The height of the light emitting element LE may be about 5.5 μm but is not limited thereto.

Each of the plurality of light emitting elements LE may be formed of an inorganic material such as gallium nitride (GaN).

Each of the plurality of light emitting elements LE may be formed by growing on a semiconductor substrate such as a silicon substrate or a sapphire substrate. The plurality of light emitting elements LE may be transferred onto the pixel electrode layer of the display panel (100 in FIG. 1) directly from the semiconductor substrate or through a transfer substrate. Alternatively, the plurality of light emitting elements LE may be transferred onto the organic adhesive layer 210 of the display panel 100 through an electrostatic method using an electrostatic head or a stamp method using an elastic polymer material such as PDMS (Polydimethylsiloane) or silicon as a transfer substrate.

The light emitting element LE may include a conductive layer E1, a semiconductor stack STC, a first contact electrode CTE1, a second contact electrode CTE2, and a protective film INS. As shown in FIG. 7, the semiconductor stack STC may include a first semiconductor layer SEM1, an active layer MQW, and a second semiconductor layer SEM2 sequentially arranged in the third direction DR3 on the conductive layer E1. In one or more embodiments, the semiconductor stack STC may also include a third semiconductor layer SEM3 on the second semiconductor layer SEM2.

In one or more embodiments, the third semiconductor layer SEM3 may be arranged on the organic adhesive layer 210. The third semiconductor layer SEM3 may be a semiconductor material layer having an n-type dopant that is lower than a suitable threshold value (e.g., a predetermined threshold value) and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN), where the n-type dopant is lower than a suitable threshold (e.g., predetermined threshold) value.

In one or more embodiments, the second semiconductor layer SEM2 may be arranged on the third semiconductor layer SEM3. In one or more embodiments, as shown in FIGS. 7-11, the second semiconductor layer SEM2 may be arranged on the organic adhesive layer 210. The second semiconductor layer SEM2 may be a semiconductor material layer doped with a second conductive dopant such as silicon (Si), germanium (Ge), and/or tin (Sn), for example, gallium nitride (GaN).

The active layer MQW may be arranged on the second semiconductor layer SEM2. The active layer MQW may emit light by the coupling of electron-hole pairs according to an electric signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The first semiconductor layer SEM1 may be arranged on the active layer MQW. The first semiconductor layer SEM1 may be formed of a semiconductor material layer doped with a first conductive dopant such as magnesium (Mg), zinc (Zn), calcium (Ca), strontium (Sr), barium (Ba), etc., for example, gallium nitride (GaN).

The conductive layer E1 may be arranged on one surface of the first semiconductor layer SEM1. In FIG. 7, the conductive layer E1 is illustrated as covering the entire top surface of the first semiconductor layer SEM1, but the present disclosure is not limited thereto. For example, the conductive layer E1 may be arranged on a portion of one surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) and/or p-type aluminum gallium nitride (AlGaN) doped with p-type magnesium (Mg). The superlattice layer may be omitted.

The protective film INS may be a film for protecting the top surface and the side surface of the light emitting element LE. The protective film INS may be arranged on the top surface and the side surface of the conductive layer E1 and the side surface of the semiconductor stack STC. Specifically, the protective film INS may be arranged on the top surface and the side surface of the conductive layer E1, the side surface of the first semiconductor layer SEM1, the side surface of the active layer MQW, and the side surface of the second semiconductor layer SEM2. In one or more embodiments, the protective film INS may be arranged on the side surface of the third semiconductor layer SEM3. The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A hole LEH may be formed that penetrates the conductive layer E1, the first semiconductor layer SEM1, and the active layer MQW of the light emitting element LE to expose the second semiconductor layer SEM2. The hole LEH may have a rectangular planar shape, but the present disclosure is not limited thereto. For example, the hole LEH may have a polygonal planar shape such as a circle, an ellipse, or a square.

In addition, the protective film INS may be arranged on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be arranged on at least one side surface of the semiconductor stack STC and at least one side surface and the top surface of the conductive layer E1. The first contact electrode CTE1 may be arranged on the top surface of the conductive layer E1 exposed without being covered by the protective film INS at a hole EH penetrating the protective film INS. Therefore, the first contact electrode CTE1 may be electrically connected to the conductive layer E1 though the hole EH.

The second contact electrode CTE2 may be arranged on at least one side of the semiconductor stack STC and on the top surface of at least one side of the conductive layer E1. At this time, the first contact electrode CTE1 may be arranged on the first side of the semiconductor stack STC and the first side of the conductive layer E1, while the second contact electrode CTE2 may be arranged on the second side of the semiconductor stack STC and the first side of the conductive layer E1.

The second contact electrode CTE2 may be arranged on the protective film INS arranged in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 and the second contact electrode CTE2 may be arranged on at least a portion of a side surface of the semiconductor stack STC. Among the side surfaces of the semiconductor stack STC, at least a region adjacent to a top surface of the semiconductor stack STC may be exposed without being covered by the first contact electrode CTE1 and the second contact electrode CTE2. For example, the first contact electrode CTE1 and the second contact electrode CTE2 may be spaced (e.g., spaced apart) from the top surface of the semiconductor stack STC in the third direction DR3. For example, in one or more embodiments as shown in FIG. 7, the first contact electrode CTE1 and the second contact electrode CTE2 may be spaced (e.g., spaced apart) from each other at the top surface of the conductive layer E1.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be arranged on three sides of the semiconductor stack STC. For example, when the semiconductor stack STC includes first to fourth sides, the first contact electrode CTE1 may be arranged on the first side, the second side, and the third side, and the second contact electrode CTE2 may be arranged on the second side, the third side, and the fourth side. The first contact electrode CTE1 and the second contact electrode CTE2 are arranged to be spaced (e.g., spaced apart) from each other. Therefore, the first contact electrode CTE1 and the second contact electrode CTE2 are not electrically short-circuited.

The first connection electrode BE1 connects the first contact electrode CTE1 of the light emitting element LE and the pixel electrode PXE1, PXE2, and PXE3. Each of the first connection electrodes BE1 may be arranged on the upper surface of a pixel electrode PXE1, PXE2, and PXE3 that is not covered by the organic adhesive layer 210. Further, the first connection electrode BE1 may be arranged on the top surface of the first organic adhesive layer 210 and the first contact electrode CTE1.

The second connection electrode BE2 connects the second contact electrode CTE2 of the light emitting element LE and the common electrodes CE1, CE2, and CE3. Each of the second connection electrodes BE2 may be arranged on the top surface of the common electrode CE1, CE2, and CE3 that is not covered by the organic adhesive layer 210. Further, each of the first connection electrode BE1 and the second connection electrodes BE2 may be arranged on the top surface and at least one side surface of the organic adhesive layer 210. Furthermore, the second connection electrode BE2 may be arranged on the top surface of the organic adhesive layer 210 and the second contact electrode CTE2.

Each of the first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu). Alternatively, each of the first connection electrode BE1 and the second connection electrode BE2 may be made of a transparent conductive material (TCO) such as indium tin oxide (ITO) and/or indium zinc oxide (IZO).

The second organic film 211 may be arranged to cover a portion of the side surfaces of the plurality of light emitting elements LE. Further, the second organic film 211 may be arranged to cover the first connection electrode BE1 and the second connection electrode BE2.

The third organic film 212 may be arranged on the second organic film 211. The third organic film 212 may be arranged to cover another part of the side surface of each of the plurality of light emitting elements LE. The third organic film 212 may be arranged on the protective film INS, the first contact electrode CTE1, the second contact electrode CTE2, the first connection electrode BE1, and the second connection electrode BE2 that are not covered by the second organic film 211 as shown in FIG. 7, but the present disclosure is not limited thereto. The top surface of each of the plurality of light emitting elements LE may be exposed without being covered by the third organic film 212.

The second organic film 211 and the third organic film 212 are layers for flattening the steps caused by the plurality of light emitting elements LE. When the height of the second organic film 211 is arranged to cover most of the side surface of each of the plurality of light emitting elements LE, the third organic film 212 may be omitted.

The second organic film 211 and the third organic film 212 may be formed from an acrylic resin, an epoxy resin, a phenolic resin, a polyamide resin, a polyimide resin, and/or the like.

A capping layer CAP may be arranged on the third organic film 212 and the light emitting element LE.

The capping layer CAP may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A fourth organic film 213 may be arranged on the capping layer CAP. A plurality of color filters CF1, CF2, and CF3 may be arranged on the fourth organic film 213. The plurality of color filters CF1, CF2, and CF3 may include first color filters CF1, second color filters CF2, and third color filters CF3.

The first color filter CF1 arranged in the first sub-pixel SPX1 may transmit the first light (e.g., light in the red wavelength band) and absorb or block other light. Therefore, the first sub-pixel SPX1 may emit the first light (e.g., light in the red wavelength band).

The second color filter CF2 arranged in the second sub-pixel SPX2 may transmit the second light (e.g., light in the green wavelength band) and absorb or block other light. Therefore, the second sub-pixel SPX2 may emit the second light (e.g., light in the green wavelength band).

The third color filter CF3 arranged in the third sub-pixel SPX3 may transmit the third light (e.g., light in the blue wavelength band). Accordingly, the third sub-pixel SPX3 may emit the third light (e.g., light in the blue wavelength band).

The first color filter CF1, the second color filter CF2, and the third color filter CF3 that overlap in the third direction DR3 may function as a light blocking layer that blocks light.

A fifth organic film 214 for planarization may be arranged on the plurality of color filters CF1, CF2, and CF3.

The fourth organic film 213 and the fifth organic film 214 may be formed of an acrylic resin, an epoxy resin, a phenolic resin, a polyamide resin, a polyimide resin, and/or the like.

In one or more embodiments, the first light emitting element LE1, the second light emitting element LE, and the third light emitting element LE3 may emit light of the same color. In this case, at least one of a light conversion layer (e.g., a light conversion layer including wavelength conversion particles such as quantum dots) and a color filter may be arranged to convert light emitted from the light emitting element LE of the corresponding sub-pixel SPX into light corresponding to the light emission color of the corresponding sub-pixel SPX on at least one light emitting element LE among the first sub-pixel SPX1, the second sub-pixel SPX2, and the third sub-pixel SPX3. When the first light emitting element LE1, the second light emitting element LE2, and the third light emitting element LE3 emit light of the same color, the sizes of the first light emitting element LE1, the second light emitting element LE2, and the third light emitting element LE3 may be the same or different. For example, depending on the light conversion efficiency by the light conversion layer, at least one of the size of the light emitting elements LE of the sub-pixels SPX and the area of the light emitting areas EA of the sub-pixels SPX may be differentiated.

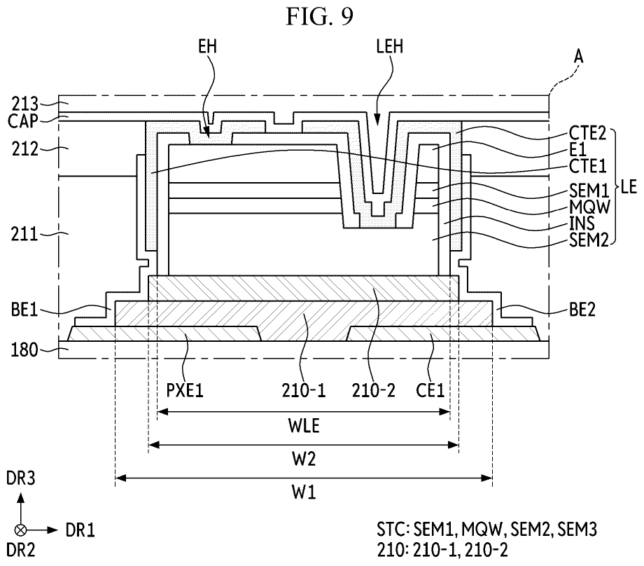

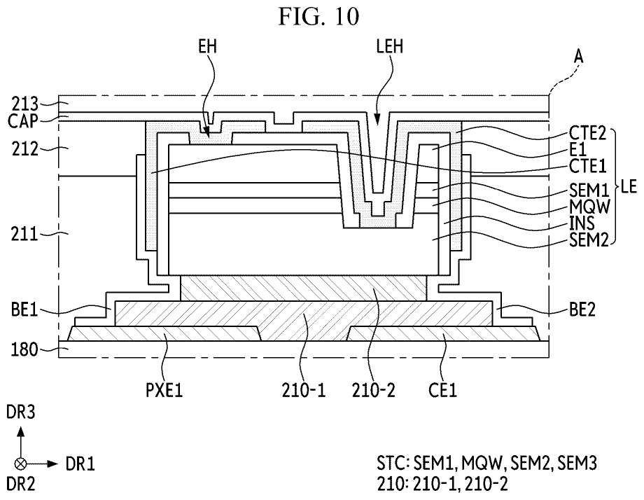

FIGS. 9 and 10 are cross-sectional views illustrating another example of the area A of FIG. 6 in detail.

FIGS. 9 and 10 differ from the embodiment of FIG. 7 in that a width W2 of the second organic adhesive layer 210-2 is not the same as a width WLE of the light emitting element LE. In the embodiment of FIG. 8, the description overlapping with the embodiment of FIG. 5 is omitted.

Referring to FIG. 9, the width W2 of the second organic adhesive layer 210-2 may be larger than the width WLE of the light emitting element LE and may be equal to or smaller than the width W1 of the first organic adhesive layer 210-1.

Referring to FIG. 10, the width W2 of the second organic adhesive layer 210-2 may be smaller than the width W1 of the first organic adhesive layer 210-1. Also, as shown in FIG. 10, the width W2 of the second organic adhesive layer 210-2 may be smaller than the width WLE of the light emitting element LE.

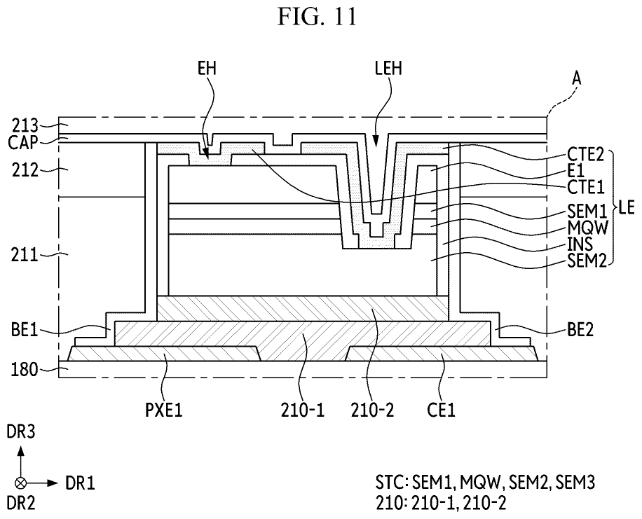

FIG. 11 is a cross-sectional view illustrating another example of the area A of FIG. 6 in detail.

FIG. 11 is different from the embodiment of FIG. 7 in that the first contact electrode CTE1 and the second contact electrode CTE2 are not arranged on the side surface of the light emitting element LE, and the first connection electrode BE1 and the second connection electrode BE2 extend along the side surface of the light emitting element LE to the top surface of the light emitting element LE. In the embodiment of FIG. 11, the description overlapping with the embodiment of FIG. 5 is omitted.

The first contact electrode CTE1 and the second contact electrode CTE2 may be spaced (e.g., spaced apart) from each other on the top surface of the light emitting element LE.

As shown in FIG. 11, the first connection electrode BE1 is connected to the conductive layer E1 of the light emitting element LE though the first contact electrode CTE1 and may be also connected to the pixel electrode PXE1, PXE2, and PXE3. The first contact electrode CTE1 may overlap with the hole EH exposing the conductive layer E1. In one or more embodiments, the first connection electrode BE1 may be connected to the conductive layer E1 of the light emitting element LE and the first connection electrode BE1 may overlap with the hole EH exposing the conductive layer E1. The first connection electrode BE1 may overlap at least a portion of the pixel electrode PXE1, PXE2, and PXE3.

As shown in FIG. 11, the second connection electrode BE2 may be connected to the second semiconductor layer SEM2 of the light emitting element LE though the second contact electrode CTE2 and may be also connected to the common electrode CE1, CE2, and CE3. The second contact electrode CTE2 may overlap with the hole LEH exposing the second semiconductor layer SEM2. In one or more embodiments, the second connection electrode BE2 may be connected to the second semiconductor layer SEM2 of the light emitting element LE and the second connection electrode BE2 may overlap the hole LEH exposing the second semiconductor layer SEM2. The second connection electrode BE2 may overlap at least a portion of the common electrode CE1, CE2, and CE3.

The first connection electrode BE1 connects the first contact electrode CTE1 of the light emitting element LE and the pixel electrode PXE1, PXE2, and PXE3. Each of the first connection electrodes BE1 may be arranged on the top surface of the pixel electrode PXE1, PXE2, and PXE3 that is not covered by the first organic adhesive layer 210-1. Further, in one or more embodiments, the first connection electrode BE1 may be arranged on the top surface of the light emitting element LE along the top surface of the first organic adhesive layer 210-1 and the side surface of the light emitting element LE. The first connection electrode BE1 may be arranged on the first contact electrode CTE1 of the top surface of the light emitting element LE.

The second connection electrode BE2 connects the second contact electrode CTE2 of the light emitting element LE and the common electrodes CE1, CE2, and CE3. Each of the second connection electrodes BE2 may be arranged on the top surface of the common electrode CE1, CE2, and CE3 that is not covered by the first organic adhesive layer 210-1. Further, in one or more embodiments, the second connection electrode BE2 may be arranged on the top surface of the light emitting element LE along the top surface of the first organic adhesive layer 210-1 and the side surface of the light emitting element LE. The second connection electrode BE2 may be arranged on the second contact electrode CTE2 on the top surface of the light emitting element LE.

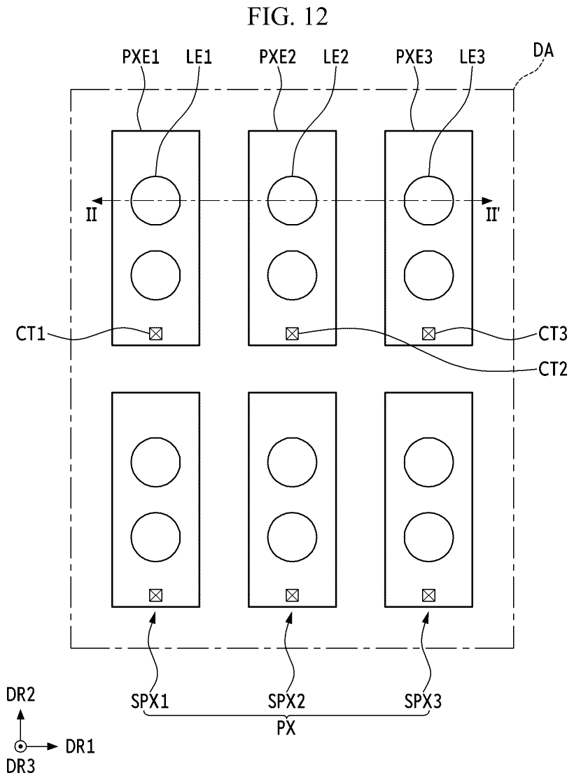

FIG. 12 is a layout diagram illustrating pixels of a display area according to one or more embodiments.

The embodiment of FIG. 12 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In the embodiment of FIG. 12, the description overlapping with the embodiment of FIG. 5 is omitted.

Referring to FIG. 12, the first sub-pixel SPX1 includes the first pixel electrode PXE1 and the first light emitting elements LE1. The second sub-pixel SPX2 includes the second pixel electrode PXE2 and the second light emitting elements LE2. The third sub-pixel SPX3 includes the third pixel electrode PXE3 and the third light emitting elements LE3. The first light emitting element LE1 may emit light of a first color, the second light emitting element LE2 may emit light of a second color, and the third light emitting element LE3 may emit light of a third color. Here, the light of the first color may be light of a red wavelength band, the light of the second color may be light of a green wavelength band, and the light of the third color may be light of a blue wavelength band. Each of the first pixel electrode PXE1, the second pixel electrode PXE2, and the third pixel electrode PXE3 may have a rectangular planar shape having a short side in the first direction DR1 and a long side in the second direction DR2.

Each of the pixel electrodes PXE1, PXE2, and PXE3 may be electrically connected to at least one transistor through pixel connection holes CT1, CT2, and CT3. For example, each of the pixel electrodes PXE1, PXE2, and PXE3 may be electrically connected to a second electrode of a fourth transistor (ST4 in FIG. 4) and a second electrode of a sixth transistor (ST6 in FIG. 4) of the corresponding sub-pixel.

A plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, two light emitting elements LE may be arranged on each of the pixel electrodes PXE1, PXE2, and PXE3.

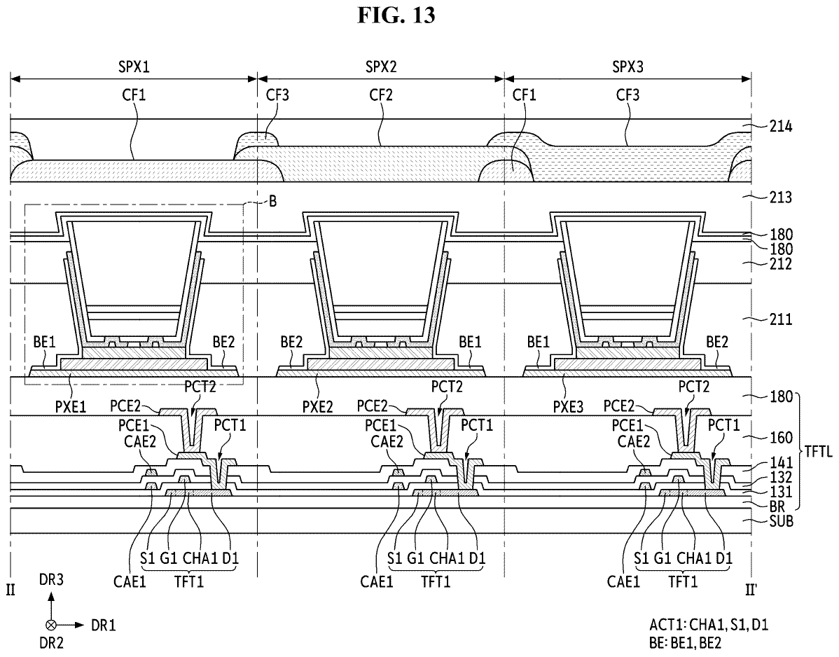

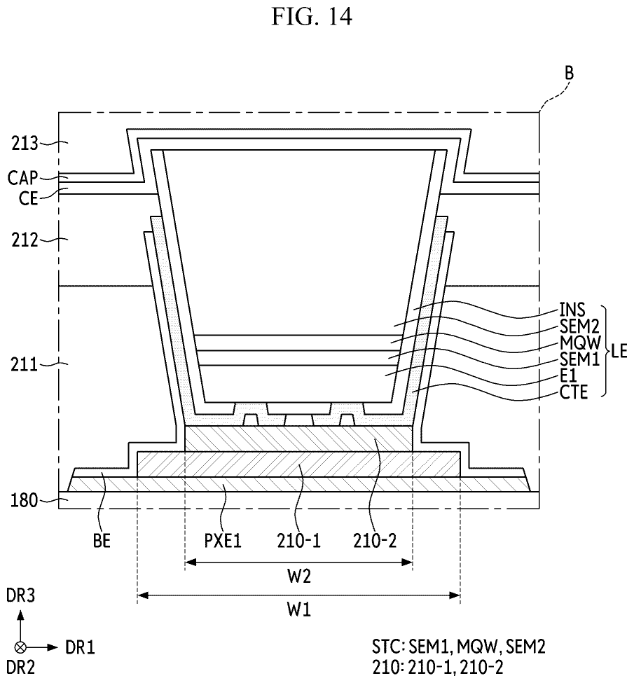

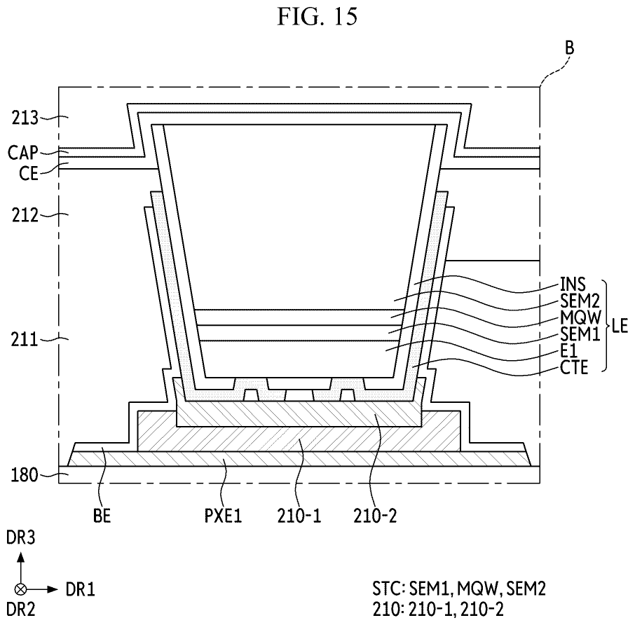

FIG. 13 is a cross-sectional view illustrating an example of a cross-section of a display panel corresponding to the line II-II′ of FIG. 12. FIG. 14 is a cross-sectional view illustrating an example of an area B of FIG. 13 in detail. FIG. 15 is a cross-sectional view illustrating another example of the area B of FIG. 13 in detail.

The embodiments of FIGS. 13 and 14 differ from the embodiments of FIGS. 6 and 7 in that the light emitting elements LE are vertical type micro LED in which each of the plurality of light emitting elements LE extends in the third direction DR3. The vertical type micro LED refers to an LED having a structure in which a first semiconductor layer SEM1, an active layer MQW, and a second semiconductor layer SEM2 are sequentially arranged in the third direction DR3, which is a vertical direction. Each of the plurality of light emitting elements LE may include a substantially vertical side surface. The light emitting elements LE may be patterned through vertical etching and may have a rectangular or square cross-sectional shape in which the width of the top surface and the width of the bottom surface are substantially the same.

In the embodiments of FIGS. 13 and 14, any description overlapping with the embodiments of FIGS. 6 and 7 will be omitted.

Referring to FIGS. 13 and 14, a pixel electrode layer may be arranged on a second planarization organic film 180. The pixel electrode layer may include a first pixel electrode PXE1, a second pixel electrode PXE2, and a third pixel electrode PXE3.

A plurality of light emitting elements LE may be arranged on an organic adhesive layer 210.

The organic adhesive layer 210 may include a first organic adhesive layer 210-1 and a second organic adhesive layer 210-2. The second organic adhesive layer 210-2 may be arranged on the first organic adhesive layer 210-1. The first organic adhesive layer 210-1 has a first width W1, and the second organic adhesive layer 210-2 has a second width W2. The first width W1 may be wider than the second width W2. In one or more embodiments, as shown in FIGS. 14-15, the conductive layer E1 may be arranged on the organic adhesive layer 210 and the light emitting element may have an inverted tapered shape, in which the width of the top surface is greater than the width of the bottom surface. However, the present disclosure is not limited thereto.

Referring to FIG. 15, in another embodiment, one side of the light emitting element LE may be buried inside the second organic adhesive layer 210-2. Accordingly, the second organic adhesive layer 210-2 may be arranged along the side surface of the light emitting element LE.

The second organic adhesive layer 210-2 may be buried inside the first organic adhesive layer 210-1. Accordingly, the first organic adhesive layer 210-1 may be arranged along the side surface of the second organic adhesive layer 210-2.

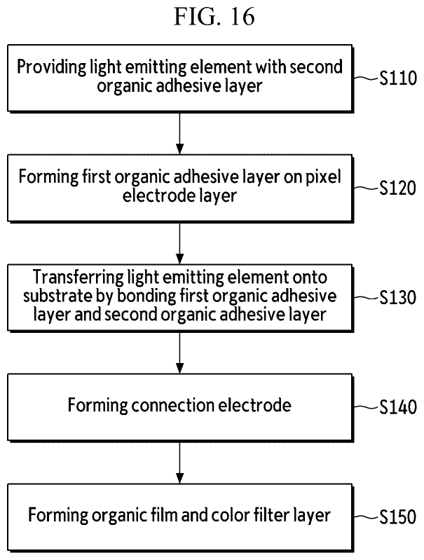

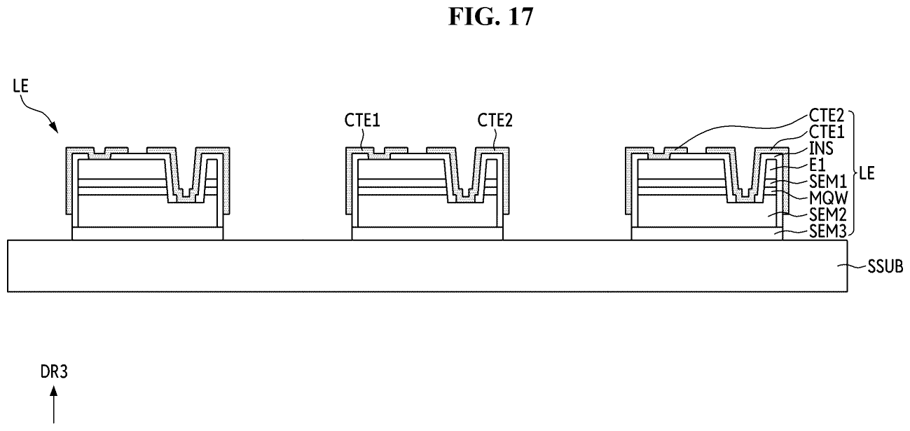

FIG. 16 is a flowchart illustrating a method of manufacturing a display device according to one or more embodiments. FIG. 17-25 are example drawings to illustrate a method of manufacturing a display device according to one or more embodiments.

Hereinafter, a method for manufacturing a display device according to one or more embodiments will be described in detail by connecting FIG. 16 with FIGS. 17-25 . In FIG. 17-25, cross-sections corresponding to the line I1-I1′ of FIG. 5 are illustrated for convenience of explanation.

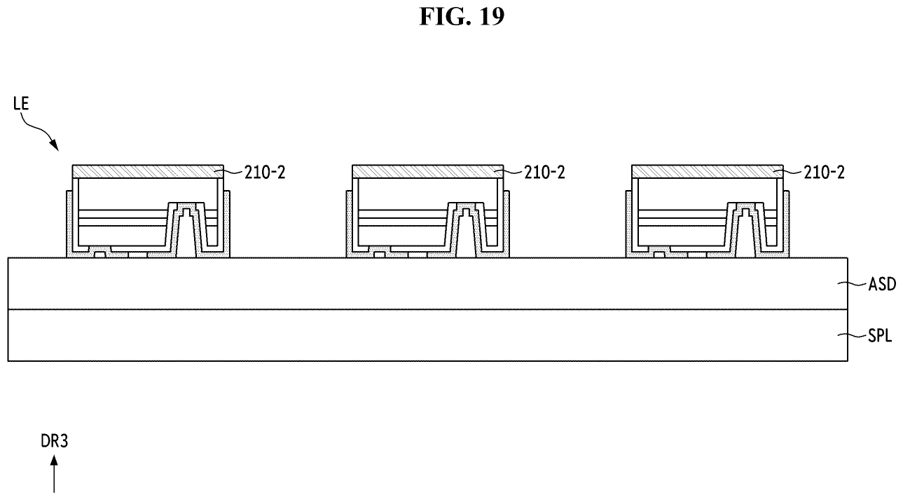

First, referring to FIGS. 17 and 19, a light emitting element LE having a second organic adhesive layer 210-2 arranged on one surface may be prepared. (S110 in FIG. 16)

The light emitting element LE is a device grown on a semiconductor substrate SSUB and may be the light emitting element LE described with reference to FIGS. 6 and 7.

The semiconductor substrate SSUB may be a silicon wafer substrate or a sapphire substrate.

A third semiconductor material layer, a second semiconductor material layer, an active material layer, a first semiconductor material layer, and a conductive material layer are formed on the semiconductor substrate SSUB, and the third semiconductor material layer, the second semiconductor material layer, the active material layer, the first semiconductor material layer, and the conductive material layer are etched to form a semiconductor stack including the second semiconductor layer, the active layer, the first semiconductor layer, and the conductive layer, respectively.

Then, the light emitting element LE grown on the semiconductor substrate SSUB may be transferred to one or more first substrates SUB-1. For convenience of explanation, in one or more embodiments, transfer to a single relay substrate is described, but it is not limited thereto. Hereinafter, the relay substrate is referred to as the first substrate SUB-1.

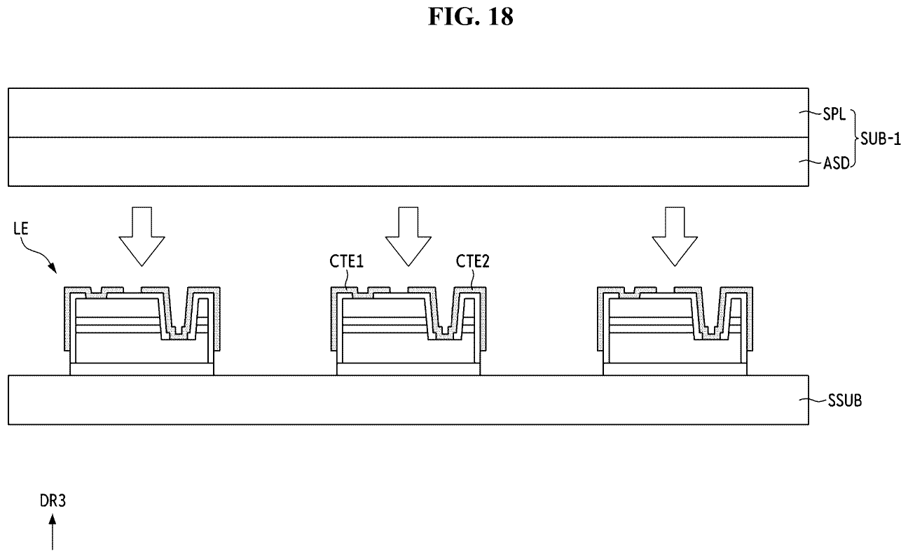

In one or more embodiments, referring to FIG. 18, the first substrate SUB-1 may include a support layer SPL and an adhesive layer ASD. The support layer SPL may be made of a material that is transparent and mechanically stable so that light may pass through it. For example, the support layer SPL may include a transparent polymer such as polyester, polyacrylic, polyoxy, polyethylene, polystyrene, polyethylene terephthalate, and/or the like.

The adhesive layer ASD having adhesive strength may be arranged on the support layer SPL.

The adhesive layer ASD may include an adhesive material for adhering the light emitting element LE. For example, the adhesive material may be a siloxane-based organic polymer, such as an organosilicon compound such as polydimethylsiloane (PDMS). The adhesive material may have fluidity.

As shown in FIG. 19, the second organic adhesive layer 210-2 may be formed on one surface of the light emitting element LE.

The second organic adhesive layer 210-2 may be formed of the same material as the adhesive layer ASD but is not limited thereto. The adhesive strength or adhesive strength of the second organic adhesive layer 210-2 may be the same as that of the adhesive layer ASD of the first substrate SUB-1.

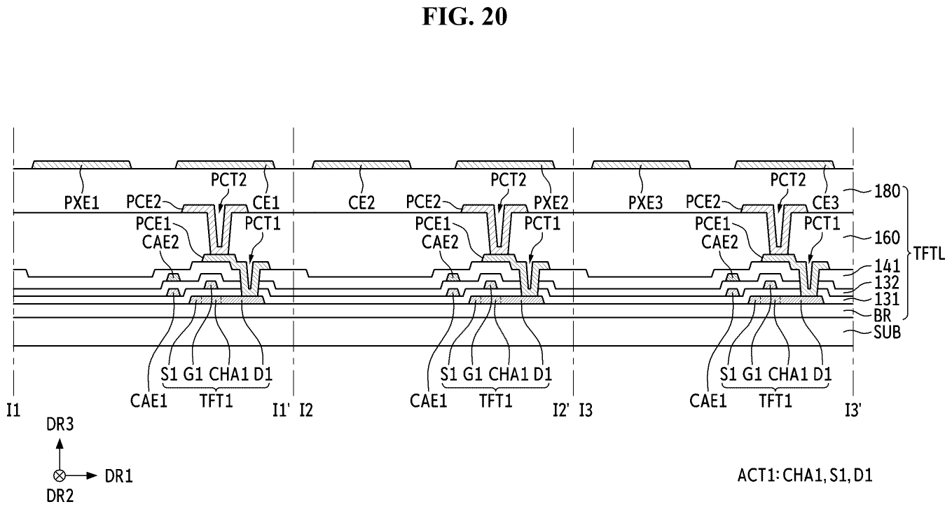

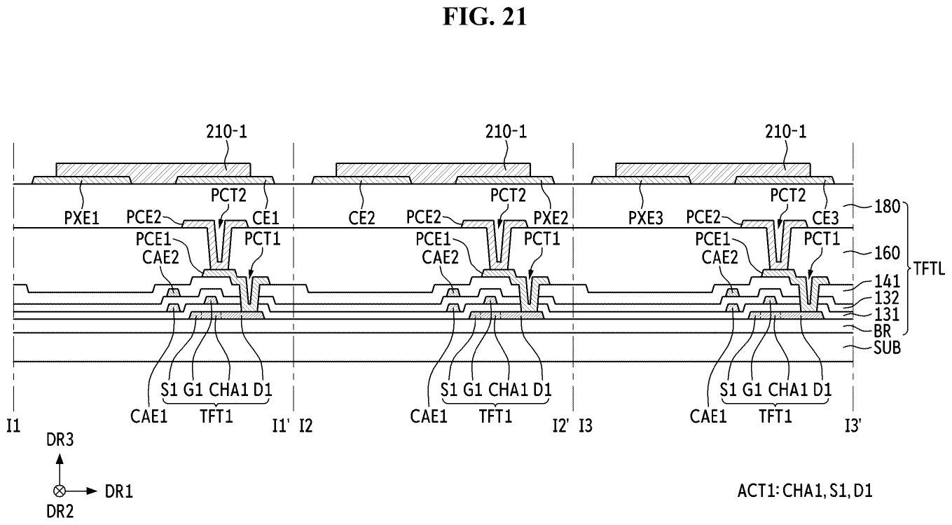

Second, as shown in FIGS. 20 and 21, the first organic adhesive layer 210-1 is formed on the pixel electrodes PXE1, PXE2, and PXE3 and the common electrodes CE1, CE2, and CE3. (S120 in FIG. 16)

The first organic adhesive layer 210-1 may be the same material as the second organic adhesive layer 210-2 or may be a different material.

For example, the first organic adhesive layer 210-1 may be formed of an acrylic resin, an epoxy resin, a phenolic resin, a polyamide resin, a polyimide resin, and/or the like.

If the adhesive strength of the first organic adhesive layer 210-1 is too high, contaminants such as dust may easily adhere to the first organic adhesive layer 210-1 before the light emitting element LE is transferred to the first organic adhesive layer 210-1. If contaminants adhere to the first organic adhesive layer 210-1, the adhesive strength with the light emitting element LE may be weakened. Furthermore, if the adhesive strength of the first organic adhesive layer 210-1 is too weak, there is a problem that the light emitting element LE may not adhere well to the first organic adhesive layer 210-1 when the light emitting element LE is transferred or may fall out of the first organic adhesive layer 210-1.

On the other hand, as in one or more embodiments, when the first organic adhesive layer 210-1 arranged on the substrate and the second organic adhesive layer 210-2 arranged on one side of the light emitting element LE are provided, even if the bonding strength of each of the first organic adhesive layer 210-1 and the second organic adhesive layer 210-2 is not made very strong, the first organic adhesive layer 210-1 and the second organic adhesive layer 210-2 may provide a stronger bonding strength than when only one organic adhesive layer of the first organic adhesive layer 210-1 or the second organic adhesive layer 210-2 is present through physical bonding and chemical bonding.

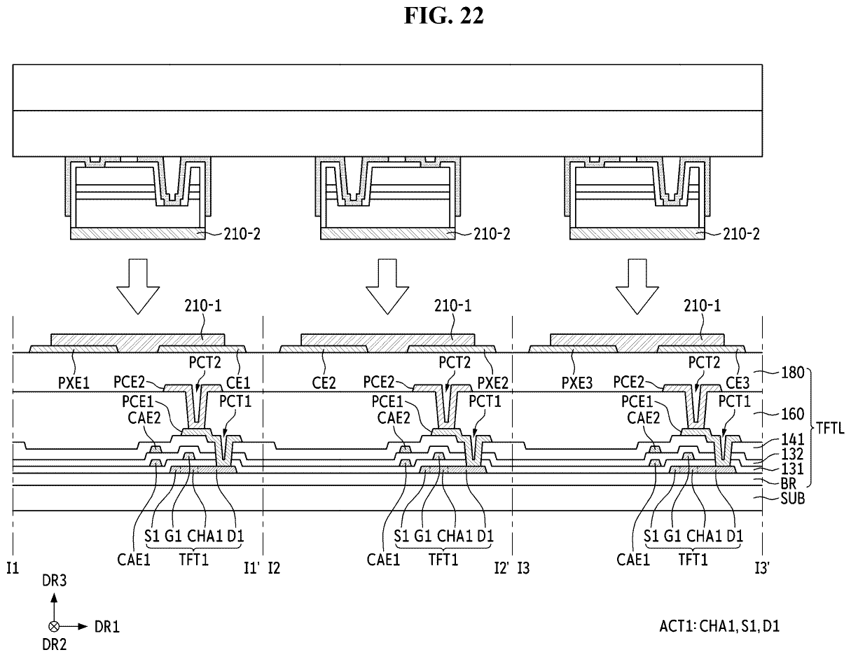

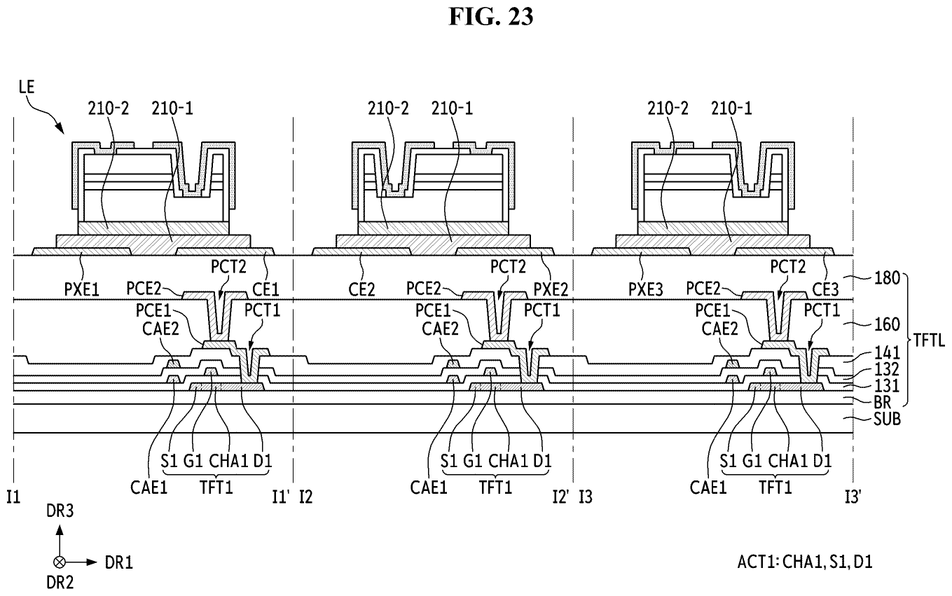

Third, referring to FIG. 22 and FIG. 23, the first organic adhesive layer 210-1 and the second organic adhesive layer 210-2 are bonded to transfer the light emitting element LE on the first substrate SSUB onto the substrate SUB. (S130 in FIG. 16)

For example, referring to FIG. 22, the first substrate SSUB is arranged on the substrate SUB so that the second organic adhesive layer 210-2 on the light emitting element LE on the first substrate SSUB faces the first organic adhesive layer 210-1. Then, the second organic adhesive layer 210-2 of the light emitting element LE and the first organic adhesive layer 210-1 of the substrate SUB are brought into contact and then heat and pressure are applied to the first organic adhesive layer 210-1 and the second organic adhesive layer 210-2. Accordingly, the first organic adhesive layer 210-1 and the second organic adhesive layer 210-2 may be physically and chemically bonded to each other.

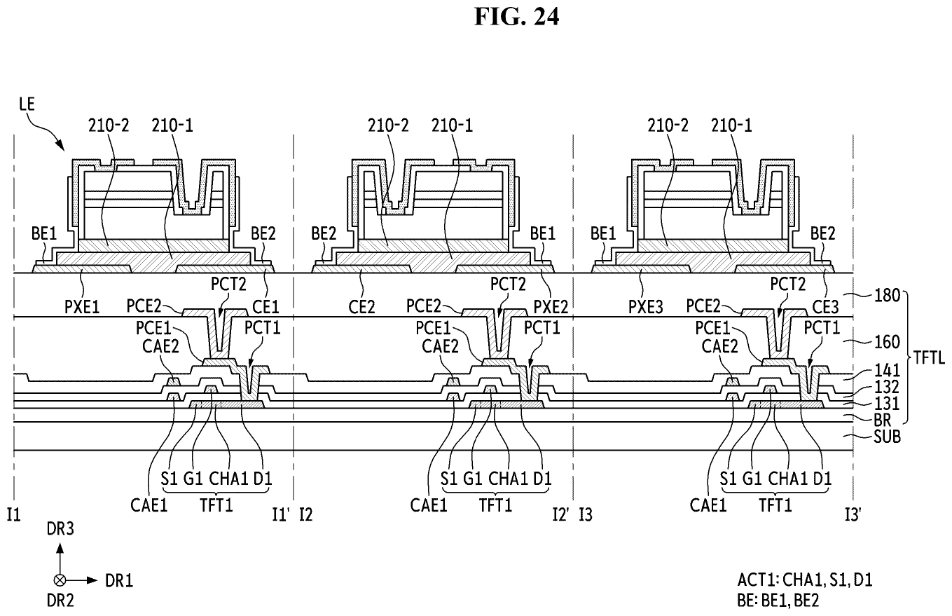

Fourth, referring to FIG. 24, the connection electrodes BE1 are formed. (S140 in FIG. 16)

The first connection electrodes BE1 for connecting the first contact electrode CTE1 of the light emitting element LE and the pixel electrode PXE (e.g., PXE1,PXE2, PXE3) and second connection electrodes BE2 for connecting the second contact electrode CTE2 and the common electrode CE are formed.

Fifth, an organic film and a color filter layer are formed sequentially. (S150 in FIG. 16)

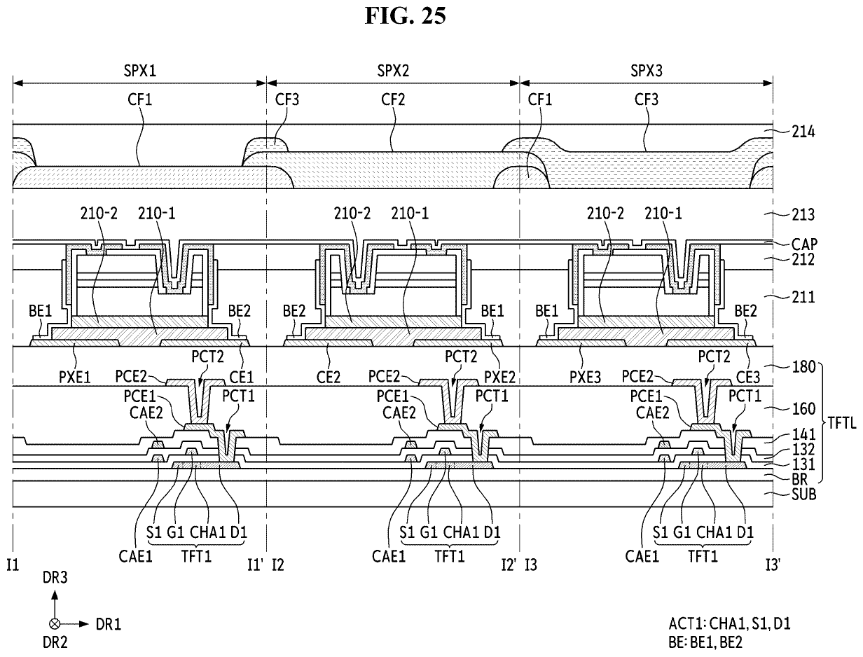

Referring to FIG. 25, a second organic film 211 and a third organic film 212 are formed to fix the light emitting elements LE and flatten the steps caused by the light emitting elements LE.

Then, a capping layer CAP is formed on the third organic film 212 and the light emitting elements LE.

Then, a fourth organic film 213 is formed on the capping layer CAP.

Then, a first color filter CF1, a second color filter CF2, and a third color filter CF3 are formed on the fourth organic film 213.

Then, a fifth organic film 214 is formed on the first color filter CF1, the second color filter CF2, and the third color filter CF3.

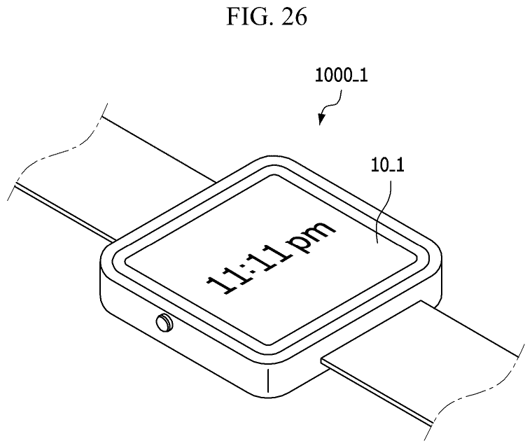

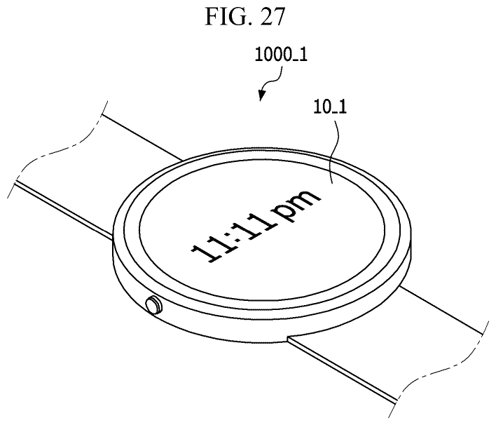

FIGS. 26 and 27 are example drawings illustrating a smart watch including a display device according to one or more embodiments.

Referring to FIGS. 26 and 27, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

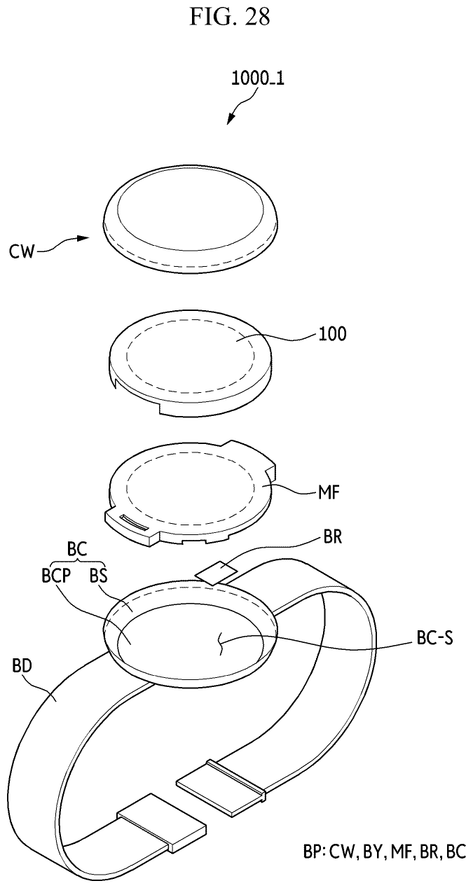

FIG. 28 is an exploded perspective view of a smart watch including a display device according to one or more embodiments.

Referring to FIG. 28, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to be around (e.g., to surround) the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a suitable curvature (e.g., a predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

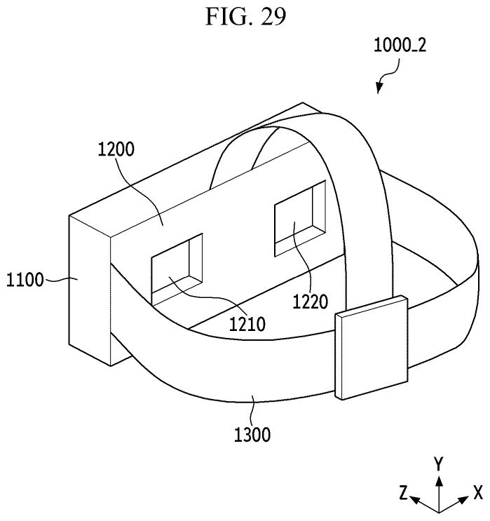

FIG. 29 is example views of a virtual reality (VR) device including a display device according to one or more embodiments.

Referring to FIG. 29, a head mounted display device 1000_2 according to one or more embodiments includes a display device housing 1100, a housing cover 1200, a first eyepiece 1210, a second eyepiece 1220, and head mounted band 1300.

The display device housing 1100 houses a display device. A head mounted display device 1000_2 according to one or more embodiments further include a first optical member disposed between the first display device and the first eyepiece 1210.

The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIG. 29, the present disclosure is not limited thereto. The first eyepiece 1210 and the second eyepiece 1220 may also be combined into one.

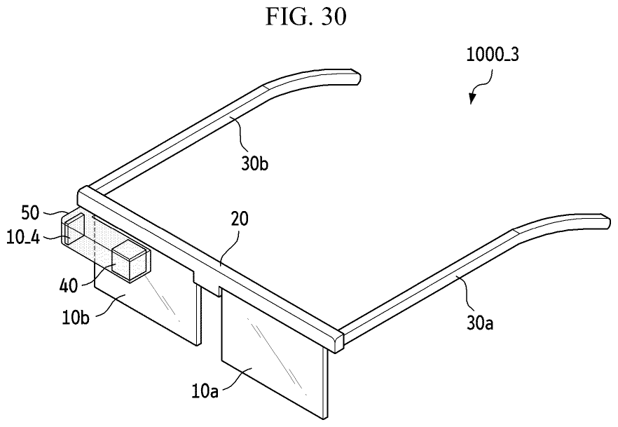

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 30 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 30 is an example view of a VR device including a display device according to one or more embodiments. FIG. 30 illustrates a VR device 1000_3 to which a display device 10_4 according to one or more embodiments has been applied.

Referring to FIG. 30, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

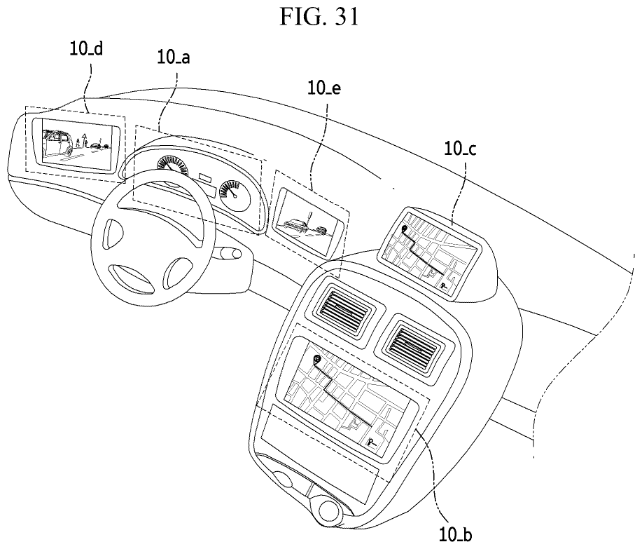

In FIG. 30, a case where the VR device 1000_3 is a glasses-type display device including the eyeglass frame legs 30a and 30b is illustrated as an example. That is, the VR device 1000_3 according to the embodiment is not limited to the one illustrated in FIG. 31 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 30, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

FIG. 31 is an example view illustrating a vehicle instrument cluster and center fascia including display devices according to one or more embodiments. FIG. 26 illustrates a vehicle to which display devices 10_a through 10_e according to one or more embodiments have been applied.

Referring to FIG. 31, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

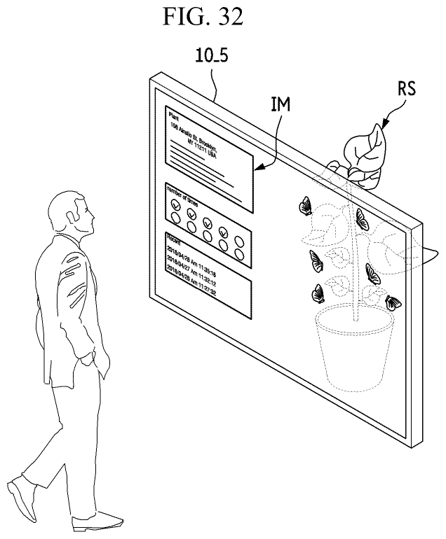

FIG. 32 is an example view of a transparent display device including a display device according to one or more embodiments.

Referring to FIG. 32, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode and a common electrode on the substrate;
a first organic adhesive layer on the pixel electrode and the common electrode;
a second organic adhesive layer on the first organic adhesive layer; and
a light emitting element on the second organic adhesive layer, the light emitting element comprising a semiconductor stack, a first contact electrode, and a second contact electrode.

2. The display device of claim 1, wherein a width of the first organic adhesive layer is greater than a width of the second organic adhesive layer.

3. The display device of claim 2, wherein the width of the second organic adhesive layer is equal to or smaller than a width of the light emitting element.

4. The display device of claim 1, wherein the first organic adhesive layer and the second organic adhesive layer comprise different materials.

5. The display device of claim 1, wherein the first organic adhesive layer and the second organic adhesive layer comprise a same material.

6. The display device of claim 1, wherein the first contact electrode extends laterally from a top surface of the light emitting element, and the second contact electrode extends laterally from the top surface of the light emitting element and is spaced from the first contact electrode.

7. The display device of claim 6, further comprising a first connection electrode connecting the pixel electrode and the first contact electrode, and a second connection electrode connecting the common electrode and the second contact electrode.

8. The display device of claim 1, wherein the light emitting element further comprises:
a conductive layer on the semiconductor stack; and
a protective film on side surfaces of the conductive layer and side surfaces of the semiconductor stack,
wherein the first contact electrode is on the protective film and is connected to the conductive layer that is exposed and not covered by the protective film,
wherein the second contact electrode is on the protective film and is in a hole penetrating the conductive layer and a portion of the semiconductor stack.

9. The display device of claim 1, wherein the semiconductor stack further comprises:
a first semiconductor layer on the second organic adhesive layer, the first semiconductor layer comprising a semiconductor material layer doped with a first conductive dopant;
an active layer on the first semiconductor layer; and
a second semiconductor layer on the active layer, the second semiconductor layer comprising a semiconductor material layer doped with a second conductive dopant,
wherein the first contact electrode is on a first side of the first semiconductor layer, a first side of the active layer, and a portion of a first side of the second semiconductor layer,
wherein the second contact electrode is on a second side of the first semiconductor layer, a second side of the active layer, and a portion of a second side of the second semiconductor layer.

10. A method for manufacturing a display device comprising:
forming a second organic adhesive layer on one surface of a light emitting element on a first substrate;
forming a first organic adhesive layer on a pixel electrode and a common electrode on a second substrate;
adhering the first organic adhesive layer and the second organic adhesive layer to transfer the light emitting element onto the second substrate; and
forming a first connection electrode connecting the pixel electrode and a first contact electrode of the light emitting element and a second connection electrode connecting the common electrode and a second contact electrode of the light emitting element.

11. The method of claim 10, wherein the first substrate comprises a light transmitting support layer and an adhesive layer on the light transmitting support layer and having adhesive strength,
wherein the light emitting element is adhered to the adhesive layer,
wherein the adhesive strength between the first organic adhesive layer and the second organic adhesive layer is stronger than the adhesive strength between the adhesive layer of the first substrate and the light emitting element.

12. The method of claim 11, wherein the adhesive layer of the first substrate and the second organic adhesive layer comprise a same material.

13. The method of claim 12, wherein the first organic adhesive layer and the second organic adhesive layer comprise different materials.

14. The method of claim 11, wherein the first organic adhesive layer and the second organic adhesive layer comprise a same material.

15. The method of claim 12, wherein in the transferring the light emitting element onto the second substrate by bonding the first organic adhesive layer and the second organic adhesive layer,
the first substrate is located on the second substrate so that the first organic adhesive layer and the second organic adhesive layer face each other and are brought into contact, and heat and pressure are applied between the first organic adhesive layer and the second organic adhesive layer to physically and chemically bond the first organic adhesive layer and the second organic adhesive layer, and the first substrate is separated and removed from the light emitting element.

16. The method of claim 10, wherein a width of the first organic adhesive layer is greater than a width of the second organic adhesive layer.

17. The method of claim 16, wherein the width of the second organic adhesive layer is equal to or smaller than a width of the light emitting element.

18. The method of claim 10, wherein the forming the second organic adhesive layer on the one surface of the light emitting element on the first substrate comprises:
forming a second semiconductor material layer, an active material layer, a first semiconductor material layer, and a conductive material layer on a semiconductor substrate;
etching the second semiconductor material layer, the active material layer, the first semiconductor material layer, and the conductive material layer to form light emitting elements, each of the light emitting elements comprising a second semiconductor layer, an active layer, a first semiconductor layer, and a conductive layer;
forming a protective material layer around each of the light emitting elements, and patterning the protective material layer to form a protective film;
forming the first contact electrode and the second contact electrode on the protective film using a mask pattern;
transferring the light emitting elements to the first substrate so that the conductive layer of each of the light emitting elements faces the first substrate; and
forming the second organic adhesive layer on the second semiconductor material layer.

19. The method of claim 10, further comprising sequentially forming an organic layer for planarizing the light emitting element and a color filter overlapping the light emitting element.

20. An electronic device comprising:
a display panel;
a window on the display panel; and
a bottom cover located below the display panel,
wherein the display panel comprises:
a substrate;
a pixel electrode and a common electrode on the substrate;
a first organic adhesive layer on the pixel electrode and the common electrode;
a second organic adhesive layer on the first organic adhesive layer; and
a light emitting element on the second organic adhesive layer, the light emitting element comprising a semiconductor stack, a first contact electrode, and a second contact electrode.
